(19) United States
(12) Patent Application Publication
(10) Pub. No.: US 2024/0372053 A1
(43) Pub. Date: Nov. 7, 2024

(54) LIGHT-EMITTING DEVICE AND DISPLAY DEVICE HAVING THE SAME

(71) Applicant: EPISTAR CORPORATION, Hsinchu (TW)

(72) Inventors: Hsin-Ying WANG, Hsinchu (TW); Jhih-Yong YANG, Hsinchu (TW); Chien-Chih LIAO, Hsinchu (TW); Chao-Hsing CHEN, Hsinchu (TW); Jheng-Long HUANG, Hsinchu (TW); Ching-Hsing SHEN, Hsinchu (TW); Hui-Fang KAO, Hsinchu (TW)

(21) Appl. No.: 18/654,733

(22) Filed: May 3, 2024

(30) Foreign Application Priority Data
May 5, 2023 (TW) 112116857

(51) Int. Cl. H01L 33/62; H01L 27/15

(52) U.S. Cl. CPC H01L 33/62; H01L 27/15

(57) ABSTRACT

A light-emitting device includes: a semiconductor stack, including a first semiconductor layer and a plurality of mesas spaced apart from each other on the first semiconductor layer, wherein the plurality of mesas each includes a second semiconductor layer, the first semiconductor layer and the second semiconductor layer have different conductivity types; a contact metal formed on the semiconductor stack, including a plurality of first contact parts located between the mesas and electrically connected to the first semiconductor layer, and a plurality of second contact parts located on the mesas and electrically connected to the second semiconductor layer; a first insulating structure formed on the contact metal, including a plurality of first openings corresponding to the first contact parts and a plurality of second openings corresponding to the second contact parts; a current spreading electrode formed on the first insulating structure, including a first current spreader and a plurality of second current spreaders, wherein the first current spreader is located between the mesas and filled in the first openings to connect the first contact parts and the second current spreaders are formed on the mesas and filled in the second openings to connect the second contact parts; a second insulating structure formed on the current spreading electrode, including a third opening on the first current spreader and a plurality of fourth openings formed on the second current spreaders; and an electrode pad structure formed on the second insulating structure, including at least one first electrode pad filled in the third opening to connect to the first current spreader, and a plurality of second electrode pads filled in the fourth openings to connect the second current spreaders.

### CROSS-REFERENCE TO RELATED APPLICATIONS

This application claims priority to and the benefit of Taiwan patent application No. 112116857 filed on May 5, 2023, and the content of which is incorporated by reference in its entirety.

### BACKGROUND

### Technical Field

The present application relates to a light-emitting device and display device having the same and, more particularly, to a light emitting device having an array of light-emitting units and a display apparatus having the same.

### Description of the Related Art

Light-emitting devices of solid-state lighting device have the characteristics of low power consumption, high brightness, high color rendering index (CRI) and compact size. Thus, light-emitting devices have been widely used in lighting and display apparatus. For example, light-emitting devices can replace the pixels of conventional liquid crystal display and achieve high quality display image. While the light-emitting devices are incorporated into display apparatus, the light-emitting diode with qualified photoelectric characteristics and the display apparatus with improved image quality are also desired.

### SUMMARY

A light-emitting device includes: a semiconductor stack, including a first semiconductor layer and a plurality of mesas spaced apart from each other on the first semiconductor layer, wherein the plurality of mesas each includes a second semiconductor layer, the first semiconductor layer and the second semiconductor layer have different conductivity types; a contact metal formed on the semiconductor stack, including a plurality of first contact parts located between the mesas and electrically connected to the first semiconductor layer, and a plurality of second contact parts located on the mesas and electrically connected to the second semiconductor layer; a first insulating structure formed on the contact metal, including a plurality of first openings corresponding to the first contact parts and a plurality of second openings corresponding to the second contact parts; a current spreading electrode formed on the first insulating structure, including a first current spreader and a plurality of second current spreaders, wherein the first current spreader is located between the mesas and filled in the first openings to connect the first contact parts and the second current spreaders are formed on the mesas and filled in the second openings to connect the second contact parts; a second insulating structure formed on the current spreading electrode, including a third opening on the first current spreader and a plurality of fourth openings formed on the second current spreaders; and an electrode pad structure formed on the second insulating structure, including at least one first electrode pad filled in the third opening to connect to the first current spreader, and a plurality of second electrode pads filled in the fourth openings to connect the second current spreaders.

A light-emitting device includes: a semiconductor stack, including a first semiconductor layer and a plurality of mesas spaced apart from each other on the first semiconductor layer, wherein the plurality of mesas each includes a second semiconductor layer, the first semiconductor layer and the second semiconductor layer have different conductivity types; a contact metal formed on the semiconductor stack, including a plurality of first contact parts located between the mesas and electrically connected to the first semiconductor layer, and a plurality of second contact parts located on the mesas and electrically connected to the second semiconductor layer; a first insulating structure formed on the contact metal, including a plurality of first openings corresponding to the first contact parts and a plurality of second openings corresponding to the second contact parts; and an electrode pad structure formed on the first insulating structure, including a first electrode pad filled in the first openings to connect to the first contact parts, and a plurality of second electrode pads filled in the second openings to connect the second contact parts; wherein the first electrode pad includes a protrusion located outside the plurality of mesas and extending toward an edge of the light-emitting device.

### BRIEF DESCRIPTION OF THE DRAWINGS

FIG. 1A shows a plan view of a light-emitting device 1 in accordance with a first embodiment of the present application.

FIG. 1B shows a cross-sectional view of the light-emitting device 1.

FIGS. 2A to 2F show plan views of each structure during a manufacturing method for the light-emitting device 1.

FIG. 3A shows a plan view of a light-emitting device 2 in accordance with a second embodiment of the present application.

FIG. 3B shows a cross-sectional view of the light-emitting device 2.

FIG. 4 shows a plan view of a light-emitting device 3 in accordance with a third embodiment of the present application.

FIG. 5A shows a plan view of a light-emitting device 4 in accordance with a fourth embodiment of the present application.

FIG. 5B shows a cross-sectional view of the light-emitting device 4.

FIG. 6A shows a plan view of a light-emitting device 5 in accordance with a fourth embodiment of the present application.

FIG. 6B shows a cross-sectional view of the light-emitting device 5.

FIG. 7A shows a plan view of a light-emitting device 6 in accordance with a fourth embodiment of the present application.

FIG. 7B shows a cross-sectional view of the light-emitting device 6.

FIG. 8 shows a display device 1000 in accordance with an embodiment of the present application.

FIG. 9 shows a display device 2000 in accordance with an embodiment of the present application.

### DETAILED DESCRIPTION

In order to make the description of the present application more detailed and complete, the following description of the embodiments and collaborating with the relevant illustrations can be referred to. However, the examples shown below are used to illustrate the light-emitting device of the present application, and the present application is not limited to the following embodiments. In addition, the dimensions, materials, shapes, relative arrangements, etc. of the elements described in the embodiments in this specification are not limited to the description, and the scope of the present application is not limited to these, but is merely a description. In addition, the size or positional relationship of the elements shown in each figure may be exaggerated for clear description. Furthermore, in the following description, in order to appropriately omit detailed descriptions, elements of the same or similar nature are shown with the same names and symbols.

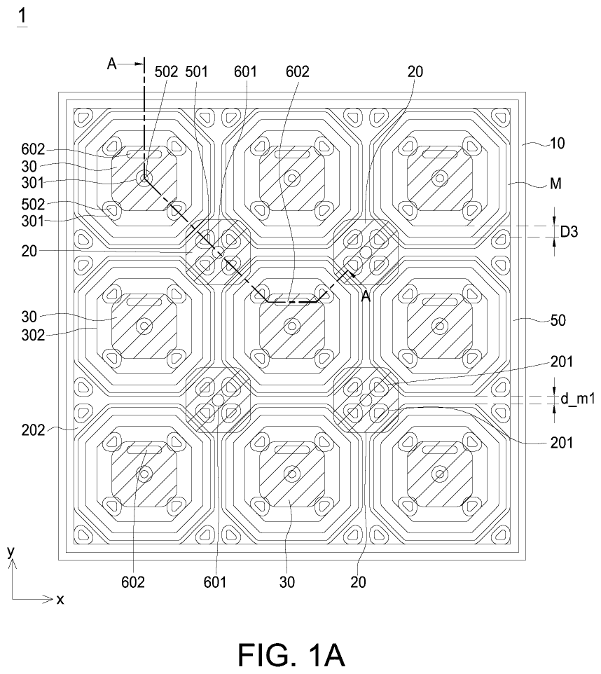

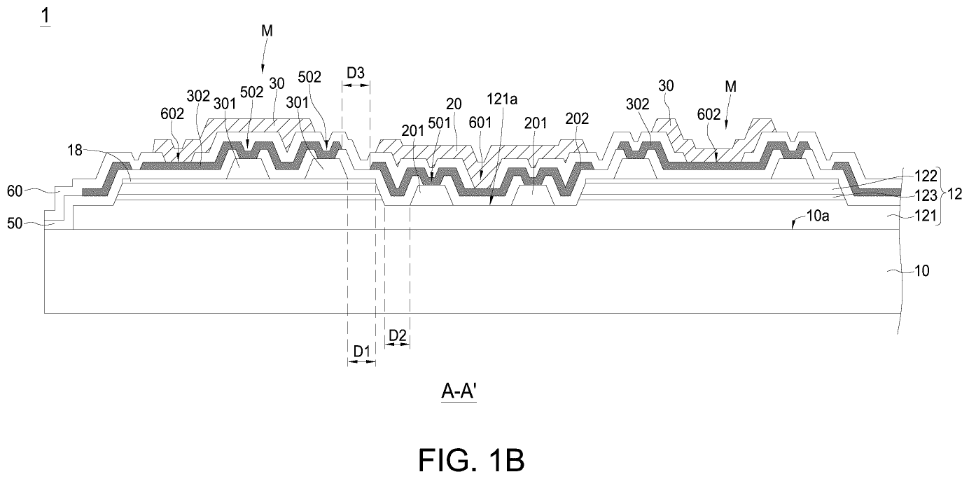

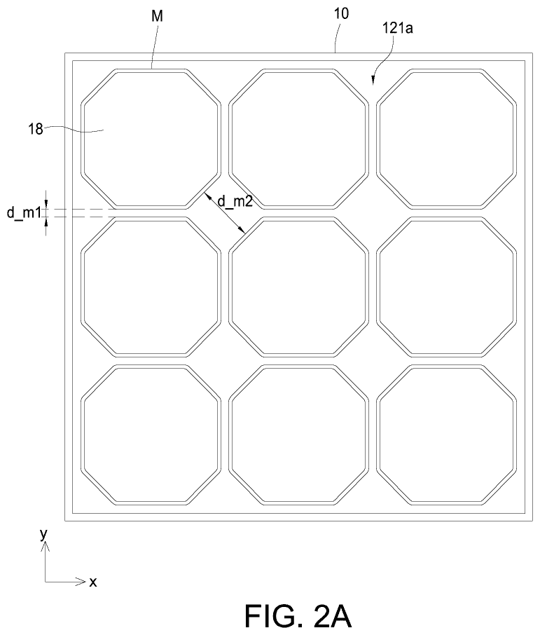

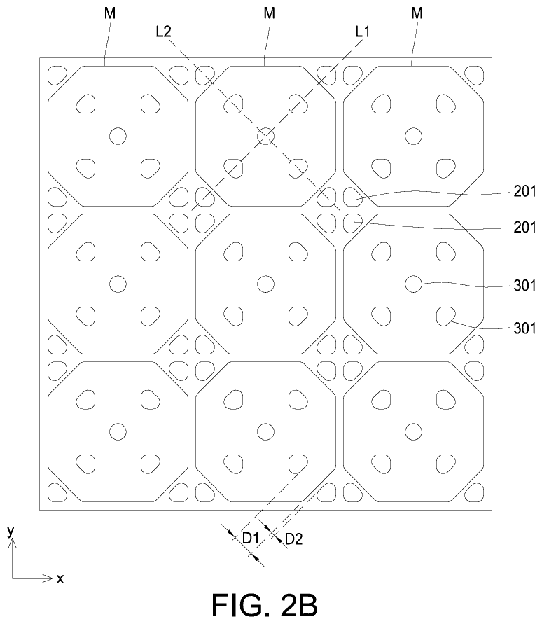

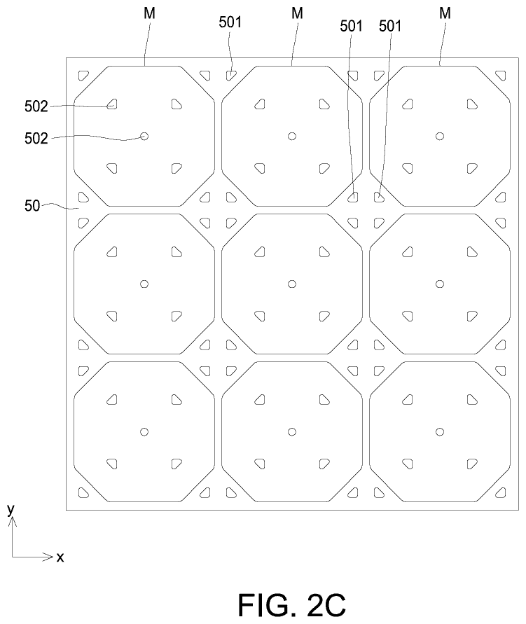

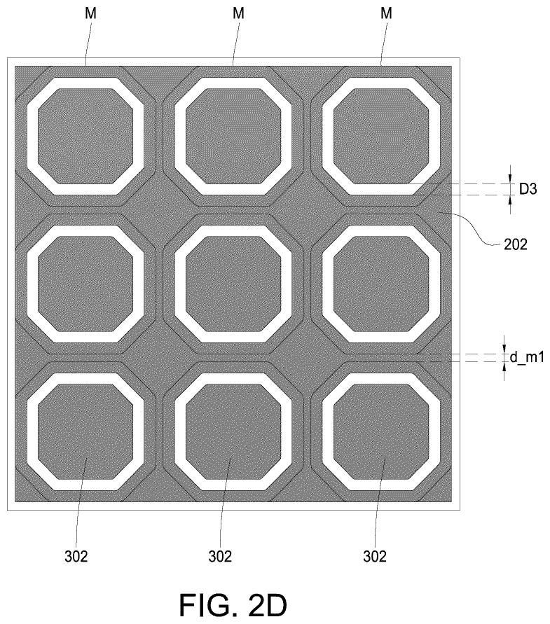

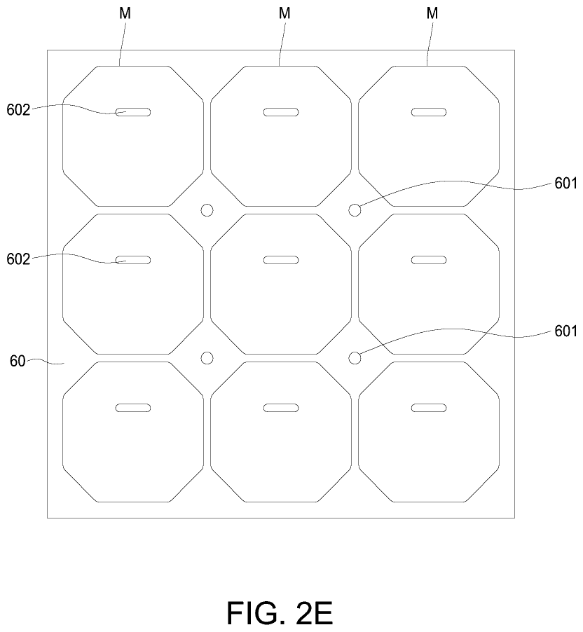

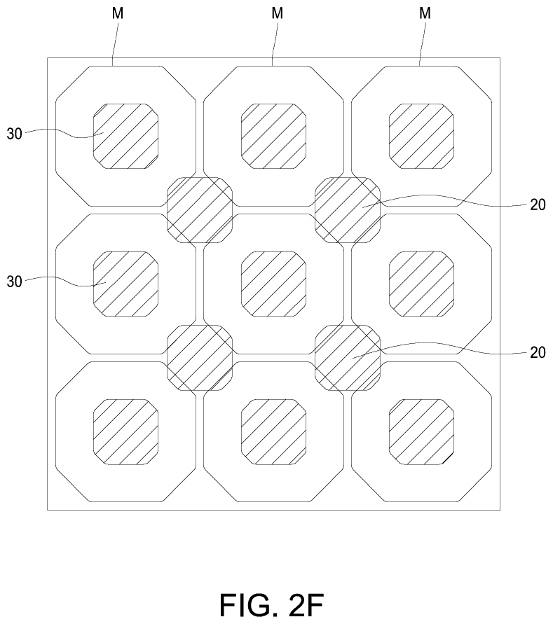

FIG. 1A shows a plan view of a light-emitting device 1 in accordance with a first embodiment of the present application. FIG. 1B shows a cross-sectional view taken along A-A′ line in FIG. 1A. FIGS. 2A to 2F show plan views of each structure during a manufacturing method for the light-emitting device 1.

As shown in FIG. 1A, FIG. 1B and FIG. 2A, a semiconductor stack 12 and the transparent conductive layer 18 are formed on a top surface 10a of a substrate 10. The semiconductor stack 12 includes a first semiconductor layer 121, an active region 123 and a second semiconductor layer 122 sequentially stacked on the substrate 10. Then, parts of the second semiconductor layer 122, the active region 123 and the first semiconductor layer 121 are removed to form a plurality of semiconductor mesas M, and an upper surface 121a of the first semiconductor layer 121 around the semiconductor mesas M is exposed, that is, each semiconductor mesa M is surrounded by the upper surface 121a of the first semiconductor layer 121. The method for removing parts of the second semiconductor layer 122, the active region 123 and the first semiconductor layer 121 includes etching. In the present application, the naming and the label of each layer are kept the same before and after any step of the manufacturing processes for the conciseness of the description. The semiconductor mesa M can be named mesa M for short. In one embodiment, a minimum distance d_m1 is set between two adjacent mesas M. In one embodiment, d_m1 ranges from 5 μm to 50 μm. In a plan view, the mesa M has a maximum width ranging from 20 μm to 500 μm. In one embodiment, the mesa M has a maximum width ranging from 20 μm to 100 μm. In one embodiment, as shown in FIGS. 1A and 2A, the mesa M is a polygon, and the plurality of mesas M are arranged in an array along x-direction and y-direction, so in that the light-emitting device includes an array of light-emitting units. As shown in FIGS. 1A and 2A, a minimum distance d_m2 is set between two adjacent mesas M in directions of positive 45 degrees and negative 45 degrees rotation from the x-axis, where d_m2 is greater than d_m1. In one embodiment, d_m2 ranges from 10 μm to 50 μm. Nevertheless, the embodiments of the present application are not limited thereto. The area, quantity, shape and arrangement of the mesas M can have different designs. In addition, the area of each mesa M can be the same or different, and the plurality of mesas M can be disposed in a staggered arrangement.

Next, a transparent conductive layer 18 is formed on the second semiconductor layer 122 of the plurality of mesas M. In another embodiment of the manufacturing method for forming the mesas M, after forming both the semiconductor stack 12 and the transparent conductive layer 18 on the top surface 10a of the substrate 10, parts of the first semiconductor layer 121, the active region 123, the second semiconductor layer 122 and the transparent conductive layer 18 are removed at the same time. The upper surface 121a of the first semiconductor layer 121 is exposed, thereby forming the plurality of mesas M and the transparent conductive layer 18 on the mesas M. In another embodiment (not shown), the transparent conductive layer 18 can be omitted.

The substrate 10 can be a growth substrate. The substrate 10 includes GaAs or GaP for growing AlGaInP based semiconductor thereon. The substrate 10 includes Al₂O₃, GaN, SiC or AlN for growing InGaN based or AlGaN based semiconductor thereon. In one embodiment, the substrate 10 can be a patterned substrate; that is, the substrate 10 includes patterned structures (not shown) on the top surface 10a. In one embodiment, the light generated from the semiconductor stack 12 is refracted, reflected or scattered by the patterned structures, thereby increasing the light extraction of the light-emitting device. In addition, the patterned structures lessen or suppress the dislocation caused by lattice mismatch between the substrate 10 and the semiconductor stack 12, thereby improving the epitaxy quality of the semiconductor stack 12. The patterned structures and the substrate 10 have the same material or different materials. In the embodiment that the patterned structures have materials different from that of the substrate 10, the material of the patterned structures includes silicon oxide, silicon nitride, silicon oxynitride and other insulating materials.

In an embodiment of the present application, the semiconductor stack 12 is formed on the substrate 10 by metal-organic chemical vapor deposition (MOCVD), molecular beam epitaxy (MBE), hydride vapor epitaxy (HVPE) or ion plating such as sputtering or evaporating.

In one embodiment, the semiconductor stack 12 further includes a buffer structure (not shown) between the first semiconductor layer 121 and the substrate 10. The buffer structure reduces the lattice mismatch and suppresses dislocation, thereby improving epitaxy quality. The material of the buffer structure includes GaN, AlGaN, or AlN. In an embodiment, the buffer structure includes a plurality of sub-layers (not shown) and the sub-layers include the same materials or different materials. In one embodiment, the buffer structure includes two sub-layers formed by different methods. For example, a first sub-layer of the buffer structure is formed by sputtering and a second sub-layer of the buffer structure is formed by MOCVD. In another embodiment, the buffer structure further includes a third sub-layer. The third sub-layer is grown by MOCVD, and the growth temperature of the second sub-layer is different from the growth temperature of the third sub-layer. In an embodiment, the first, second, and third sub-layers include the same material, such as AlN. In one embodiment, the first semiconductor layer 121 and the second semiconductor layer 122 are, for example, cladding layers or confinement layers. The first semiconductor layer 121 and the second semiconductor layer 122 have different conductivity types, different electrical properties, different polarities or different dopants for providing electrons or holes. In one embodiment, the first semiconductor layer 121 includes n-type dopants and the second semiconductor layer 122 includes p-type dopants. For example, the first semiconductor layer 121 is composed of n-type semiconductor and the second semiconductor layer 122 is composed of p-type semiconductor. The active region 123 is formed between the first semiconductor layer 121 and the second semiconductor layer 122. When being driven by a current, electrons and holes are combined in the active region 123 to convert electrical energy into optical energy for illumination. The wavelength of the light generated by the light-emitting device 1 or by the semiconductor stack 12 can be adjusted by changing the physical properties and chemical composition of the semiconductor stack 12 such as one or more layers in the active region 123.

The material of the semiconductor stack 12 includes III-V compound semiconductor such as AlₓIn_{y}Ga_{(1-x-y)}N (i.e., AlInGaN base) or AlₓIn_{y}Ga_{(1-x-y)} P (i.e., AlInGaP base), where 0≤x, y≤1; x+y≤1. When the material of the semiconductor stack 12 includes AlInGaP based material, the semiconductor stack 12 emits red light having a wavelength between 610 nm and 650 nm or yellow light having a wavelength between 550 nm and 570 nm. When the material of the semiconductor stack 12 includes AlInGaN based material, the semiconductor stack 12 emits blue light or deep blue light having a wavelength between 400 nm and 490 nm, green light having a wavelength between 490 nm and 550 nm or UV light having a wavelength between 250 nm and 400 nm. The active region 123 can be a single hetero-structure (SH), a double hetero-structure (DH), a double-side double hetero-structure (DDH), or a multi-quantum well (MQW) structure. The material of the active region 123 can be i-type, p-type or n-type semiconductor.

The transparent conductive layer 18 can spread current and provide good electrical contact with the second semiconductor layer 122, such as ohmic contact. The transparent conductive layer 18 is transparent to the light generated from the active region 123. For example, the transparent conductive layer 18 has a transmittance of more than 80% to the light generated from the active region 123. The material of the transparent conductive layer 18 can be metal, metal oxide or graphene. The metal material includes Au, NiAu, etc. The metal oxide includes ITO, AZO, GZO, ZnO, IZO, etc.

It should be noted that the mesas M formed in the step of FIG. 2A are also shown in FIGS. 2B to 2F to show the relative position of each layer. Next, referring to FIGS. 1A, 1B and 2B, a contact metal is formed on the mesas M and the upper surface 121a of the first semiconductor layer 121 around the mesas M. The contact metal includes a plurality of first contact parts 201 located on the upper surface 121a of the first semiconductor layer 121 between the mesas M and electrically connected to the first semiconductor layer 121, and a plurality of second contact parts 301 located on the mesas M and electrically connected to the second semiconductor layer 122. In any one embodiment of the present application, the quantity of first contact parts 201 on the upper surface 121a between two adjacent mesas M can be single or multiple, and the quantity of the second contact parts 301 on the second semiconductor layer 122 of any mesa M can be single or multiple. For example, as shown in FIGS. 1A and 2B, four first contact parts 201 on the upper surface 121a of the first semiconductor layer 121 between four adjacent mesas M compose a first contact group. Five second contact parts 301 on the second semiconductor layer 122 of any one of the mesas M compose a second contact group. The first contact parts 201 are not only formed between adjacent mesas M, but also surrounds any one of the mesas M. For example, as shown in FIGS. 1A and 2B, the semiconductor stack 12 of the light-emitting device 1 includes nine mesas M, eight of which are located around the light-emitting device 1. The first contact parts 201 are disposed on the upper surface 121a of the first semiconductor layer 121 among the eight mesas M and the edge of the light-emitting device 1. Therefore, the first contact parts 201 surround any one of the mesas M. More specifically, the first contact parts 201 are disposed in the four quadrants around any one of the mesas M. In one embodiment, in the plan view, the plurality of second contact parts 301 in one second contact group are arranged in radial symmetry with respect to a center of the mesa M. In one embodiment, the first contact parts 201 and the second contact parts 301 are disposed along lines L1 and L2 shown in FIG. 2B, wherein the lines L1 and L2 are the directions rotated by minus 45 degrees and plus 45 degrees in x-direction, respectively. The plurality of second contact parts 301 in the second contact group can also be arranged axially symmetrically. In one embodiment shown in FIGS. 1B and 2B, a minimum distance between the second contact part 301 located above the mesa M and the edge of the mesa M (i.e., the edge of the second semiconductor layer 122) is D1. A minimum distance between the first contact part 201 located around the mesa M and the edge of the mesa M is D2, where D1 is greater than D2. In one embodiment, D2 is greater than or equal to 5 μm. In another embodiment, D1 is greater than 10 μm.

The contact metal includes chromium (Cr), titanium (Ti), tungsten (W), gold (Au), aluminum (Al), rhodium (Rh), indium (In), tin (Sn), beryllium (Be), germanium (Ge), nickel (Ni), platinum (Pt), silver (Ag), a laminated stack of the above materials or an alloy of the above materials. The first contact parts 201 and the second contact parts 301 can be formed in the same or different processes. The first contact parts 201 and the second contact parts 301 may include the same or different materials. In one embodiment, the first contact parts 201 and the second contact parts 301 are formed in the same process, and include the same material and substantially the same thickness. In one embodiment, the thicknesses of the first contact parts 201 and the second contact parts 301 range from 1 μm to 3 μm, and the widths thereof range from 3 μm to 30 μm. In one embodiment, the width of the first contact part 201 is smaller than d_m2. In another embodiment, the transparent conductive layer 18 is omitted and the second contact parts 301 can be directly formed on the second semiconductor layer 122.

Next, referring to FIGS. 1A, 1B and 2C, a first insulating structure 50 is formed on the mesas M and the first semiconductor layer 121. The first insulating structure 50 includes insulating material. The first insulating structure 50 covers the mesas M, the upper surface 121a of the first semiconductor layer 121 and the contact metal, and includes a plurality of first openings 501 corresponding to and exposing the first contact parts 201 and a plurality of second openings 502 corresponding to and exposing the second contact parts 301. In one embodiment, the maximum width of the first opening 501 is less than or equal to the maximum width of the first contact part 201, and the maximum width of the second opening 502 is less than or equal to the maximum width of the second contact part 301.

Next, referring to FIGS. 1A, 1B and 2D, a current spreading electrode is formed on the first insulating structure 50. The current spreading electrode includes a first current spreader 202 and a plurality of second current spreaders 302 that are separated from each other. The plurality of second current spreaders 302 are respectively located on the mesas M and filled in the second openings 502 to connect the second contact parts 301 of the contact metal and electrically connect the second semiconductor layer 122. The first current spreader 202 is formed between the plurality of mesas M and filled in the first opening 501 to connect the first contact part 201 of the contact metal and electrically connect the first semiconductor layer 121. In one embodiment shown in FIG. 1A, the second current spreaders 302 located above one of the mesas M overlaps all the second contact parts 301 in the second contact group on the one of the mesas M. In the plan view, the second current spreader 302 has an area larger than that of the second contact part 301 and smaller than that of the second semiconductor layer 122 beneath it. The first current spreader 202 is disposed along the gaps between the plurality of mesas M. In one embodiment, the first current spreader 202 covers the side walls of the mesas M and a part of the upper surface of the second semiconductor layer 122, and is separated from the second current spreader 302 without overlapping the second current spreader 302. In the plan view, the first current spreader 202 has, for example, a mesh shape. A minimum distance D3 is set between the first current spreader 202 and the second current spreader 302 in a horizontal direction, that is, on the upper surface of the second semiconductor layer 122. In one embodiment, D3 is greater than or equal to 5 μm. In another embodiment, D3 is smaller than D1. The current spreading electrodes 202 and 302 include metals, such as chromium (Cr), titanium (Ti), tungsten (W), gold (Au), aluminum (Al), rhodium (Rh), indium (In), tin (Sn), beryllium (Be), germanium (Ge), nickel (Ni), platinum (Pt), silver (Ag) and other metals, a laminated stack of the above materials or an alloy of the above materials. In one embodiment, the current spreading electrodes 202 and 302 include a reflective metal, such as silver or aluminum. In this way, the current spreading electrodes 202 and 302 can reflect the light generated from the semiconductor stack 12 and thereby improving the brightness of the light-emitting device 1. In addition, since the first current spreader 202 covers the side walls of each mesa M, the light emitted by each mesa M can be blocked thereby preventing the light from adjacent mesas M from interfering with each other. In one embodiment, the first current spreader 202 and the second current spreader 302 are formed in the same process, and may include the same material stack and substantially the same thickness. In one embodiment, the thickness of the current spreading electrode is smaller than the thickness of the contact metal.

Next, referring to FIGS. 1A, 1B and 2E, a second insulating structure 60 is formed on the current spreading electrode. The second insulating structure 60 includes third openings 601 located on the first current spreader 202 and fourth openings 602 correspondingly located on the second current spreaders 302. In one embodiment, in the plan view, the first opening 501 of the first insulating structure 50 and the third opening 601 of the second insulating structure 60 do not overlap, and the second opening 502 of the first insulating structure 50 and the fourth opening 602 of the second insulating structure 60 do not overlap. If the openings of the first insulating structure 50 and the second insulating structure 60 overlap, a deep opening is formed, which will affect the step coverage of an electrode pad structure subsequently formed on the openings of the second insulating structure 60. In one embodiment, in the plan view shown in FIG. 1A, the third opening 601 is located between the plurality of first contact parts 201 in the first contact group. The fourth opening 602 is located between the plurality of second contact parts 301 in the second contact group.

Each of the first insulating structure 50 and the second insulating structure 60 can be a single-layer structure or multiple-layer structure, and the materials thereof include insulating materials, such as silicon oxide, silicon nitride, silicon oxynitride, niobium oxide, hafnium oxide, titanium oxide, magnesium fluoride or aluminum oxide. In one embodiment, the first insulating structure 50 and/or the second insulating structure 60 includes one or more pairs of insulating layers with different refractive indexes. One pair of the insulating layers is composed by a first sub-layer and a second sub-layer (not shown). The first sub-layer has a different material from that of the second sub-layer and has a refractive index higher than that of the second sub-layer. By selecting materials with different refractive index and the thicknesses thereof, the first insulating structure 50 and/or the second insulating structure 60 can reflect light within a specific wavelength range and/or a specific incident angle range, that is, the first insulating structure 50 and/or the second insulating structure 60 can be a reflective structure. In one embodiment, the first insulating structure 50 and/or the second insulating structure 60 includes distributed Bragg reflector and has a reflectance of more than 60% of the dominant wavelength and/or the peak wavelength of the light-emitting device 1.

In another embodiment, the first insulating structure 50 and/or the second insulating structure 60 further includes additional layers other than the first sub-layer and the second sub-layer. For example, the first insulating structure 50 and/or the second insulating structure 60 further includes a bottom layer (not shown) between the pair(s) of the insulating layers and the semiconductor stack 12. In other words, the bottom layer is formed on the semiconductor stack 12 first, and then the first sub-layers and the second sub-layers are formed on the bottom layer. In one embodiment, the bottom layer includes insulating material which can be the same as one of the first sub-layer and the second sub-layer or different from both the first sub-layer and the second sub-layer. The thickness of the bottom layer is greater than those of the first sub-layer and the second sub-layer. In one embodiment, the bottom layer can be formed by a process different from that for forming the first sub-layer and the second sub-layer. The bottom layer, the first sub-layer and the second sub-layer are formed by deposition. In the embodiment that the bottom layer is formed by a process different from that for forming the first sub-layer and the second sub-layer, the bottom layer can be formed by chemical vapor deposition (CVD), such as plasma enhanced chemical vapor deposition (PECVD), and the first sub-layer and the second sub-layer can be formed by physical vapor deposition (PVD), such as sputtering or evaporation. In one embodiment, the bottom layer can protect the light-emitting device or the semiconductor stack, for example, prevent moisture from penetrating the light-emitting device.

In another embodiment, the first insulating structure 50 and/or the second insulating structure 60 further includes a top layer (not shown) formed on one side of the insulating structure opposite to the second semiconductor layer 122. In other words, the first sub-layers and the second sub-layers are formed on the semiconductor stack 12 first, and then the top layer is formed. The top layer includes insulating material which can be the same as one of the first sub-layers and the second sub-layers or different from both the first sub-layers and the second sub-layers. The thickness of the top layer is greater than the thicknesses of the first sub-layer and the second sub-layer. In one embodiment, the top layer can be formed by a process different from that for forming the first sub-layer and the second sub-layer. For example, the top layer is formed by CVD, such as PECVD. The first sub-layers and the second sub-layers can be formed by sputtering or evaporation. In one embodiment, the top layer can improve the robustness of the insulating structure. For example, when the insulating structure is subject to an external force, the top layer can prevent the insulating structure from being broken and damaged due to the external force.

In one embodiment, the first insulating structure 50 and/or the second insulating structure 60 further includes a dense layer (not shown) with a thickness between 50 Å and 2000 Å. The dense layer can be formed by atomic layer deposition (ALD). In one embodiment, the dense layer formed by ALD conformably covers the semiconductor stack 12. Due to the characteristic of better step coverage of the dense layer, the dense layer can protect the semiconductor stack 12, such as preventing moisture from entering the semiconductor stack 12. In other embodiments, the dense layer can be the most bottom layer or the most top layer in the first insulating structure 50 and/or the second insulating structure 60, an intermediate layer between the aforementioned bottom layer and the pair(s) of the insulating layers, or an intermediate layer between the pair(s) of the insulating layers and the top layer.

In one embodiment, the thickness of the second insulating structure 60 is greater than the thickness of the first insulating structure 50. In one embodiment, the thickness of the first insulating structure 50 and/or the second insulating structure 60 are between 0.2-5 μm. In one embodiment, the thicknesses are between 1-3 μm.

Next, referring to FIGS. 1A, 1B and 2F, an electrode pad structure is formed on the second insulating structure 60. The electrode pad structure includes a first electrode pad 20 filled in the third opening 601 and connected to the first current spreader 202, and a plurality of second electrode pads 30 located on the mesas M, filled in the fourth openings 602 and connected to the second current spreaders 302. In one embodiment, as shown in FIGS. 1A, 1B and 2F, the first electrode pad 20 is further located on the side walls of the mesas M and a part of the second semiconductor layer 122. The first electrode pad 20 and the second electrode pad 30 are electrically connected to the first semiconductor layer 121 and the second semiconductor layer 122 respectively, and are used for flip-chip bonding the light-emitting device 1 to external electronic components or power sources. In this way, the plurality of mesas M emits light and can be used as light-emitting units. The first electrode pad 20 and the second electrode pad 30 include metals, such as chromium (Cr), titanium (Ti), tungsten (W), gold (Au), aluminum (Al), indium (In), tin (Sn), nickel (Ni), platinum (Pt), a laminated stack of the above materials or an alloy of the above materials. The first electrode pad 20 and the second electrode pad 30 can be composed of a single layer or multiple layers. For example, the first electrode pad 20 and the second electrode pad 30 include Ti/Au, Ti/Pt/Au, Cr/Au, Cr/Pt/Au, Ni/Au, Ni/Pt/Au or Cr/Al/Cr/Ni/Au. In one embodiment, the thickness of the electrode pad structure is greater than the thickness of the current spreading electrode.

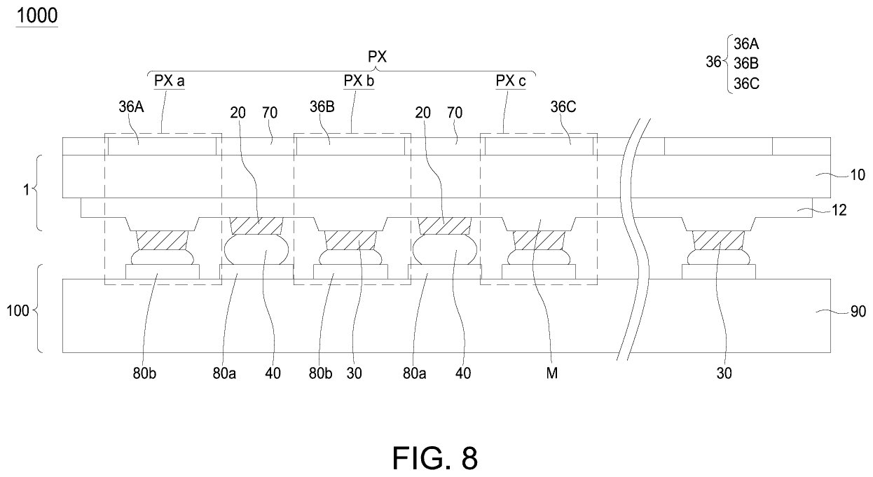

FIG. 8 shows a schematic cross-sectional view of a display device 1000 in accordance with an embodiment of the present application. As shown in FIG. 8, the display device 1000 includes light-emitting devices 1 and a driving backplane 100 connected to the light-emitting devices 1. The driving backplane 100 is used to drive the light-emitting devices 1. It should be noted that, in order to make the figure clear and concise, the light-emitting devices 1 is schematically shown in FIG. 8. The detailed structure of the light-emitting device 1 should be referred to FIG. 1A, FIG. 1B and relative descriptions.

The driving backplane 100 includes a carrier 90. A driving circuit (not shown) is provided in an interior and/or on the top of the carrier 90. A first driving electrode 80a and a second driving electrode 80b are formed on the carrier 90. The carrier 90 of the driving backplane 100 can be a flexible substrate or a rigid substrate. The flexible substrate can be made of thin glass, metal foil, plastic, polyimide, etc. The rigid substrate can be made of glass, sapphire, silicon, etc. The first driving electrode 80a and the second driving electrode 80b are electrically connected to the driving circuit. The driving circuit can be a passive matrix (PM) driving circuit or an active matrix (AM) driving circuit. The driving circuit may include but is not limited to data lines, scan lines, power lines, and active components. The active component includes, for example, field effect transistors (FETs), complementary metal oxide semiconductors (CMOS), thin film transistor (TFT), high electron mobility transistor (HEMT). The first driving electrode 80a and the second driving electrode 80b are respectively connected to the first electrode pad 20 and the second electrode pad 30 by a conductive bonding layer 40. The conductive bonding layer 40 includes solder, conductive glue, eutectic alloy, etc. After the light-emitting device 1 is turned on, each mesa M generates light to form a light-emitting unit, which can be used as the sub-pixels PX_a, PX_b and PX_c of the display device 1000. Multiple adjacent sub-pixels form a pixel PX. The size and arrangement of the sub-pixels depend on the size and the gap of the mesas M. The area of each of the mesas M can vary according to different applications. For example, the area and arrangement of the mesas M can be designed according to the color and resolution of the display device 1000.

In one embodiment, the display device 1000 further includes an insulating material (not shown) disposed between the sub-pixels PX_a-PX_c. The insulating material is formed in the gaps between the electrode pad structure, driving electrodes and the conductive bonding layer 40 of each sub-pixel. In one embodiment shown in FIG. 8, the display device 1000 may further include a wavelength modulation layer 36 (36A-36C) located on one side of the light-emitting device 1. More specifically, the wavelength modulation layer 36 can be disposed corresponding to the light extraction surfaces of at least parts of the mesas M and forms a part of the sub-pixels PX_a-PX_c. The wavelength modulation layer 36 includes color filter, multi-layered filter, a fluorescent glue or a fluorescent sheet made of phosphor material, or quantum dot materials. In one embodiment, the wavelength modulation layer 36 can be used to convert the light generated from the mesas M into different colors. For example, when the light generated from by the mesas M is blue light or ultraviolet light, the wavelength modulation layer 36A can be a red wavelength conversion layer, the wavelength modulation layer 36B can be a green wavelength conversion layer, and the wavelength modulation layer 36C can be a blue wavelength conversion layer, respectively. The wavelength modulation layers 36A-36C convert the light generated from the mesas M to red, green, and blue lights, thereby realizing a full-color display device. In one embodiment, when the light generated from the mesas M is blue light, the wavelength modulation layer 36C can be omitted or replaced with a transparent layer so that the blue light generated from the mesas M can pass. In another embodiment, the wavelength modulation layer 36 can be used to purify the color light generated from the light-emitting device 1, thereby realizing display device with wide color gamut. In another embodiment, the wavelength modulation layer 36 may include a plurality of modulation structures with different functions, such as a modulation structure for wavelength conversion and a modulation structure for color purification. In another embodiment, the display device 1000 includes an opaque layer 70 located between each sub-pixel PX_a-PX_c, such as between the wavelength modulation layer 36, or between the mesas M. In a plan view, the opaque layer 70 and the mesas M are arranged alternately, and the opaque layer 70 can be used as a black matrix. The material of the opaque layer 70 includes metal, metal oxide, photoresist, resin, glass paste, etc., and can block or absorb the lights generated from adjacent mesas M, prevent light leakage or avoid interference of the colored lights, thereby improving the contrast of the display device 1000.

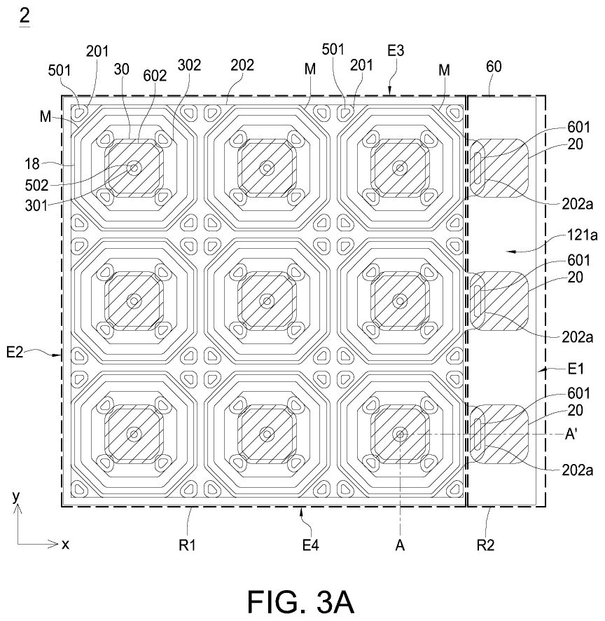

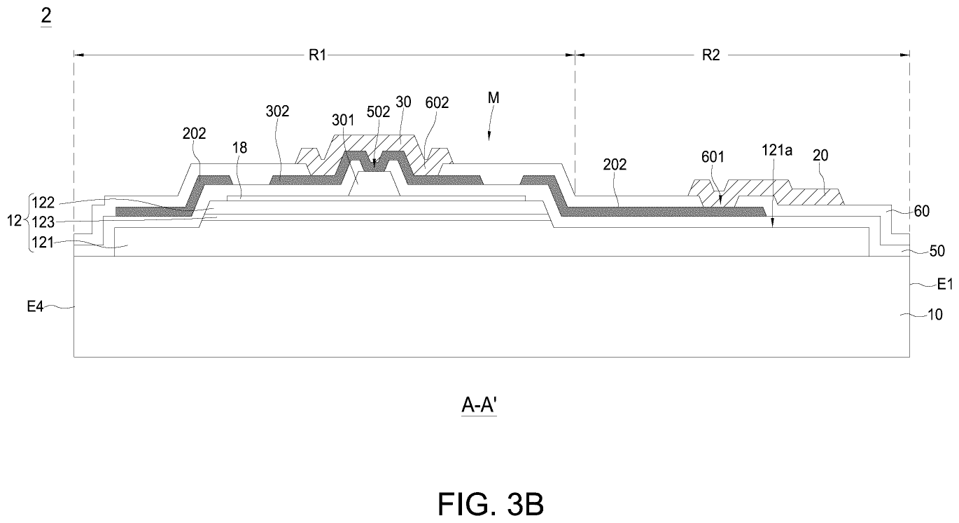

FIG. 3A shows a plan view of a light-emitting device 2 in accordance with a second embodiment of the present application. FIG. 3B shows a cross-sectional view taken along line A-A′ in FIG. 3A. Like the light-emitting device 1, the light-emitting device 2 includes the mesas M, the transparent conductive layer 18, the contact metals 201 and 301, the first insulating structure 50, the current spreading electrodes 202 and 302, the second insulating structure 60 and the electrode pad structure 20 and 30. If the details of each elements of the light-emitting device 2 are not specifically described in this embodiment and have the same name and same label as those of the light-emitting device 1, the details can be referred to the description of the light-emitting device 1, and will not be repeated.

The differences between the light-emitting device 2 and the light-emitting device 1 are described as the following. As shown in FIGS. 3A and 3B, the light-emitting device 2 includes an operational region R1 and a non-operational region R2. A plurality of mesas M is in the operational region R1. The operational region R1 can be regarded as a light-emitting region. The first current spreader 202 of the light-emitting device 2 includes a plurality of protrusions 202a located in the non-operational region R2, and on the upper surface 121a of the first semiconductor layer 121 outside the plurality of mesas M. The plurality of protrusions 202a extends toward an edge E1 of the light-emitting device 2 and an edge of the first semiconductor layer 121. The third openings 601 of the second insulating structure 60 are located on the protrusions 202a and are not located between the adjacent mesas M in the operational region R1. In one embodiment, the plurality of protrusions 202a can be provided corresponding to the arrangement of the mesas M, for example, corresponding to the columns and/or the rows of the mesas M. The plurality of first electrode pads 20 corresponds to the plurality of protrusions 202a, for example, in a one-to-one manner, and is formed on the protrusions 202a and the third opening 601 along the edge E1 of the light-emitting device 2 rather than formed between the adjacent mesas M. In other embodiments, the plurality of protrusions 202a can further extend toward other edges E2, E3, and E4 of the light-emitting device 2, and the plurality of first electrode pads 20 can be arranged corresponding to the edges where the plurality of protrusions 202a are located. In addition, on a single mesa M, the fourth opening 602 of the second insulating structure 60 overlaps with one of the second contact parts 301 and one or more second openings 502 of the first insulating structure 50. The second electrode pad 30 is electrically connected to the second semiconductor layer 122 through the second opening 502 and the fourth opening 602. In other embodiments (not shown), the first electrode pad 20 of the light-emitting device 2 has a larger area and a different shape than the second electrode pad 30, and can be configured to overlap the plurality of protrusions 202a and located on the plurality of third openings 601 at the same time.

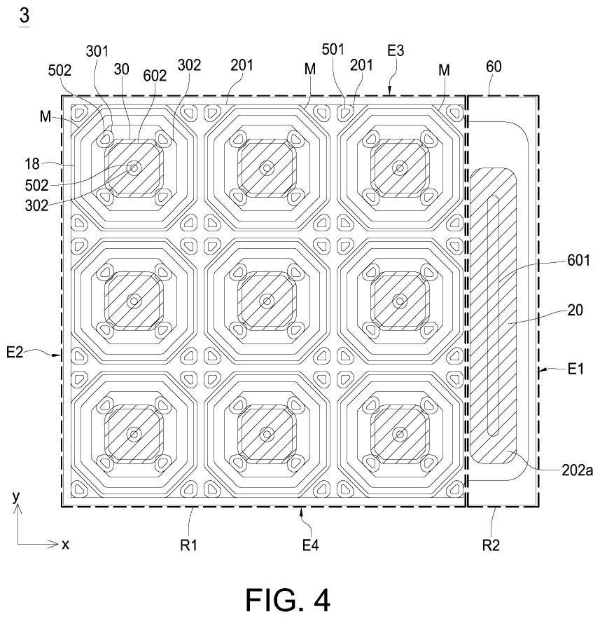

FIG. 4 shows a plan view of the light-emitting device 3 in accordance with a third embodiment of the present application. The structure of the light-emitting device 3 is like that of the light-emitting device 2. The difference is that the first current spreader 202 of the light-emitting device 3 includes a single protrusion 202a disposed along the edge E1, and the second insulating structure 60 includes a single third opening 601 located on the single protrusion 202a. The first electrode pad 20 is electrically connected to the first current spreader 202 through the third opening 601. In another embodiment (not shown), the single third opening 601 of the second insulating structure 60 can be replaced by a plurality of third openings, wherein the plurality of third openings are separately formed on the single protrusion 202a.

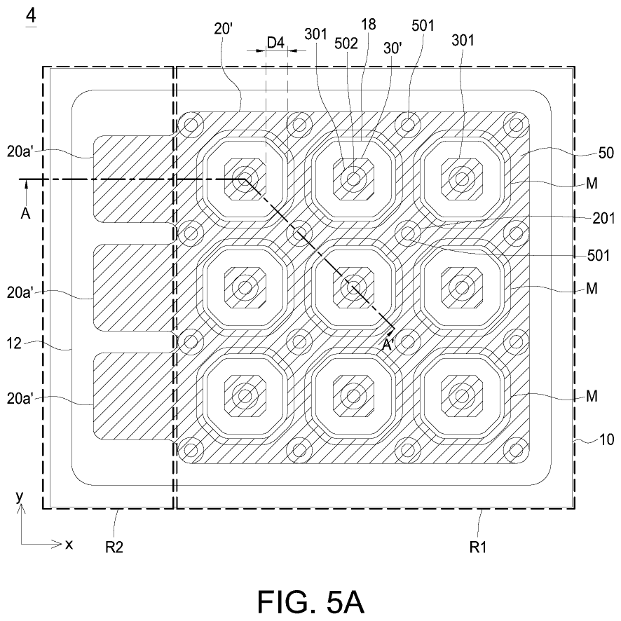

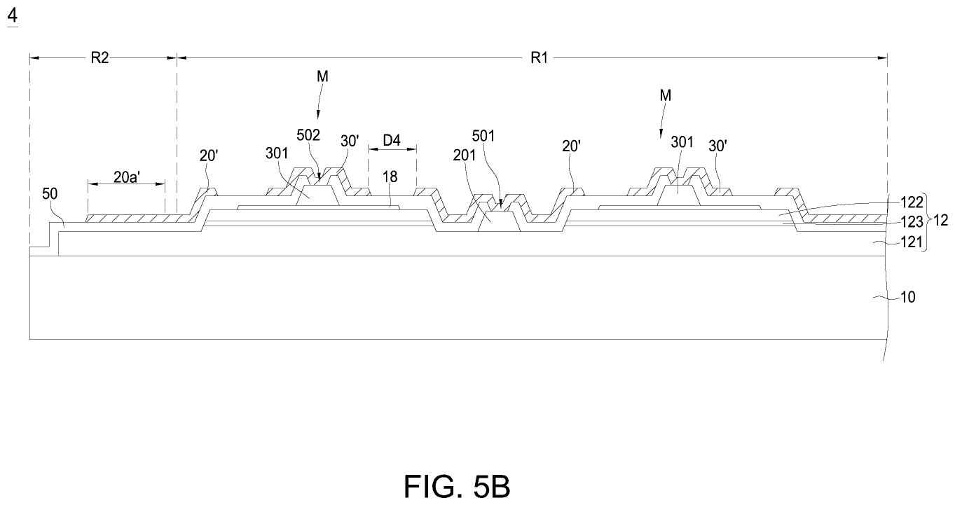

FIG. 5A shows a plan view of a light-emitting device 4 in accordance with a fourth embodiment of the present application. FIG. 5B shows a cross-sectional view taken along line A-A′ in FIG. 5A. Like the light-emitting device 2, the light-emitting device 4 includes mesas M, the transparent conductive layer 18, the contact metals 201 and 301, the first insulating structure 50, and the electrode pad structure 20′ and 30′. If the details of each elements of the light-emitting device 4 are not specifically described in this embodiment and have the same name and same label as those of the aforementioned embodiments, the details can be referred to the description of the aforementioned embodiments, and will not be repeated.

The differences between the light-emitting device 4 and the light-emitting device 2 are described as the following. As shown in FIGS. 5A and 5B, a single second contact part 301 is provided on a single mesa M, and a single first contact part 201 is provided between two adjacent mesas M. The light-emitting device 4 is devoid of the first current spreader 202. Each second electrode pad 30′ of the light-emitting device 4 is located on the first insulating structures 50 on the mesa M and is filled in the second opening 502 of the first insulating structure 50 to contact the second contact part 301. The first electrode pad 20′ is located on the first insulating structure 50 between the plurality of mesas M, and filled in the first openings 501 of the first insulating structure 50 to contact the plurality of first contact parts 201. In the plan view, the first electrode pad 20′ has, for example, a mesh shape and is located on the upper surface 121a of the first semiconductor layer 121 and extends to cover the side walls of each mesa M. A gap D4 is set between the first electrode pad 20′ and the second electrode pad 30′. In one embodiment, D4 ranges from 5 μm to 30 μm. The first electrode pad 20′ includes a plurality of protrusions 20a′ located on the upper surface 121a of the first semiconductor layer 121 outside the operational region R2 and the plurality of mesas M, and extend toward an edge of the light-emitting device 4. In one embodiment, the plurality of protrusions 20a′ is provided corresponding to the columns or the rows of the mesas M. In other embodiments, the plurality of protrusions 20a′ can further extend toward other edges of the light-emitting device 4. The protrusions 20a′ of first electrode pad 20a′ and the second electrode pad 30′ can be used to bond the light-emitting device 4 to an external electronic component or power supply in flip-chip form, so that the plurality of mesas M generates light.

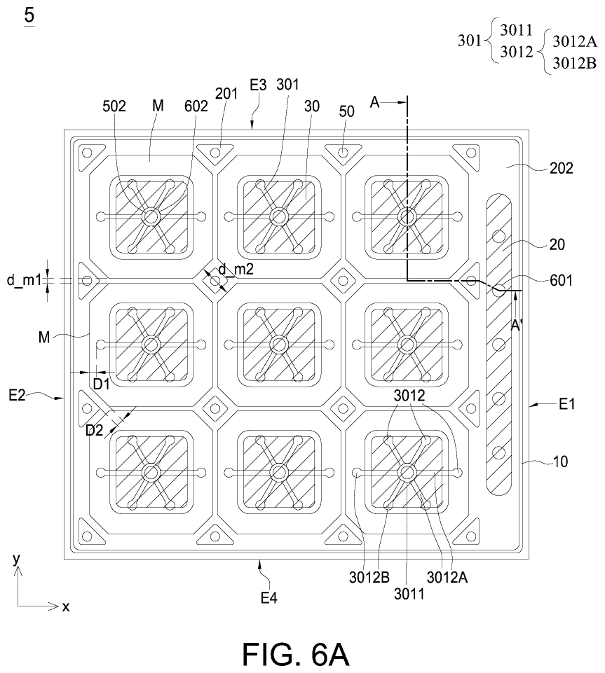

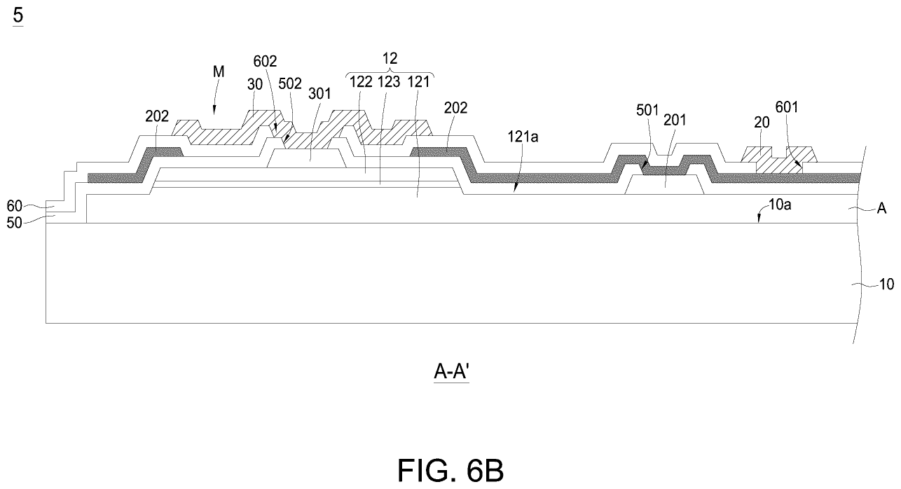

FIG. 6A shows a plan view of a light-emitting device 5 in accordance with a fifth embodiment of the present application. FIG. 6B shows a cross-sectional view taken along line A-A′ in FIG. 6A. The light-emitting device 5 is similar with the light-emitting device 3, and both of them include semiconductor mesas M, the first contact parts 201, the second contact parts 301, the first insulating structure 50, the second insulating structure 60, the first electrode pad 20 and the second electrode pads 30. If the details of each elements of the light-emitting device 5 are not specifically described in this embodiment and have the same name and same label as those of the light-emitting devices mentioned above, the details can be referred to the description of the light-emitting devices, and will not be repeated.

The difference between the light-emitting device 5 and the light-emitting device 3 is described in detail as follows. As shown in FIGS. 6A and 6B, the light-emitting device 5 is devoid of the transparent conductive layer 18 and the second current spreaders 302. That is, the second contact parts 301 directly contact the second semiconductor layer 122, and the second electrode pad 30 directly contacts the second contact part 301. In addition, the second openings 502 of the first insulating structure 50 in the light-emitting device 5 overlap with the fourth openings 602 of the second insulating structure 60, and the fourth openings 602 is larger than the second openings 502. The light-emitting device 5 has a plurality of third openings 601, and the first electrode pad 20 is electrically connected to the first current spreader 202 through the plurality of third openings 601. In this embodiment, the minimum distance D1, which is between the second contact part 301 and the edge of the semiconductor mesa M, is less than or equal to the minimum distance D2, which is between the first contact part 201 and the edge of the semiconductor mesa M.

In the embodiment, the first contact part 201 can have different shapes according to its location to achieve a more uniform current dispersion. For example, the first contact part 201 surrounded by plural semiconductor mesa M is in the shape of a rhombus, while the first contact part 201 closed to the edges E1˜E4 of the light-emitting device 5 and located in two adjacent semiconductor mesa M is in the shape of a triangle. Single second contact part 301 locates on each semiconductor mesa M, and the second contact parts 301 has a central area 3011 and a plurality of extension areas 3012. In this embodiment, the second contact parts 301 has six extension areas 3012 connected to the center area 3011 and extends radially towards the edge of the semiconductor mesa M. Specifically, each extension area 3012 has an extension part 3012A and an end part 3012B with an arc shape. The extension part 3012A extends from the central area 3011 to the edge of the semiconductor mesa M, and the end part 3012B is away from the central area 3011. The width of the extension portion 3012A is smaller than the width of the end portion 3012B. Through the design of the above-mentioned extension part 3012A and end part 3012B, it can be achieved more uniform current dispersion.

As shown in FIG. 6B, the light-emitting device 5 further includes an adhesive layer A located between the upper surface 10a of the substrate 10 and the semiconductor stack 12, and is used to connect the substrate 10 and the semiconductor stack 12. In one embodiment, the adhesive layer A may be a single layer or multiple layers (not shown). The material of the adhesive layer A may include transparent insulating materials. The transparent insulating materials include but are not limited to titanium oxide (TiO2), niobium oxide (Nb2O5), silicon oxide (SiO2), aluminum oxide (Al2O3), silicon nitride (SiN) or benzocyclobutene (BCB).

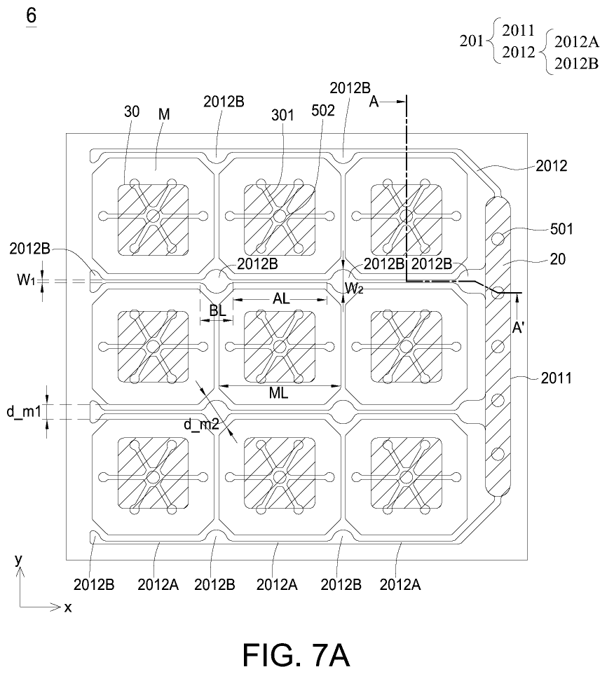

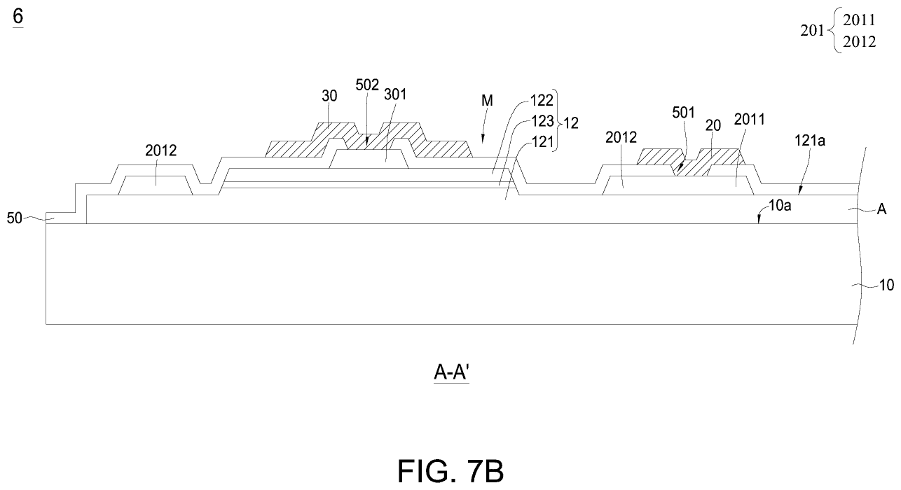

FIG. 7A shows a plan view of a light-emitting device 6 in accordance with a sixth embodiment of the present application. FIG. 7B shows a cross-sectional view taken along line A-A′ in FIG. 7A. The light-emitting device 6 is similar with the light-emitting device 3, and both of them include the semiconductor mesas M, the first contact parts 201, the second contact parts 301, the first insulating structure 50, the first electrode pad 20 and the second electrode pads 30. If the details of each elements of the light-emitting device 6 are not specifically described in this embodiment and have the same name and same label as those of the light-emitting devices mentioned above, the details can be referred to the description of the light-emitting devices, and will not be repeated.

The difference between the light-emitting device 6 and the light-emitting device 3 is described in detail as follows. The light-emitting device 6 is devoid of the second insulating structure 60, the transparent conductive layer 18, the first current spreader 202 and second current spreader 302, That is, the second contact part 301 directly contacts the second semiconductor layer 122, the first electrode pad 20 directly contacts the first contact part 201, and the second electrode pad 30 directly contacts the second contact parts 301. The first contact part 201 is disposed on the upper surface 121a of the first semiconductor layer 121 and has a current injection region 2011 and a plurality of branches 2012 connected to the current injection region 2011. The current injection region 2011 is correspondingly disposed below the first electrode pad 20, and the first electrode pad 20 is electrically connected to the current injection region 2011 through the plurality of first openings 501 of the first insulating structure 50. The plurality of branches 2012 are located between the plurality of semiconductor mesa M, thereby uniformly guiding the current to the first semiconductor layer 121. In this embodiment, each branch 2012 has a plurality of connection areas 2012A and a plurality of expansion areas 2012B. Each expansion area 2012B may be surrounded by a plurality of semiconductor mesas M and/or be disposed between two adjacent semiconductor mesas M. Each connection area 2012A is located between two adjacent expansion areas 2012B. Each connection area 2012A has a first width W1, and each expansion area 2012B has a second width W2 that is greater than the first width W1, so each branch 2012 has a varying width. For example, one of the branches 2012 in this embodiment (for example, the second branch from the top to bottom direction) in the direction away from the current injection region 2011 is in the order of expansion area 2012B-connection area 2012A-expansion area 2012B-connection area 2012A-expansion area 2012B-connection area 2012A-expansion area 2012B. Therefore, the width of the branch 2012 first becomes smaller, then becomes larger, then becomes smaller, then becomes larger, then becomes smaller, and then becomes larger in the direction away from the current injection area 2011. With this design, the current can be evenly distributed.

The first width W1 and the second width W2 are parallel to one of the edges of the light-emitting device 6, for example, along the direction parallel to the Y-axis. In the embodiment, the minimum distance d_m1 between adjacent semiconductor mesas M is smaller than the second width W2 and greater than the first width W1. Each connection area 2012A has a first length LA, and each expansion area 2012B has a second length BL. The first length LA and the second length BL are parallel to the other edge of the light-emitting device 6 and substantially perpendicular to the first width W1 and the second width W2. For example, the first length AL and the second length BL extend along the direction parallel to the X-axis. In this embodiment, the first length AL is greater than the second length BL. Each semiconductor mesa M has a maximum length ML parallel to the first length AL and the second length BL, and the maximum length ML is greater than the first length AL. In an embodiment, the second length BL may be equal to, smaller than, or larger than the first width W1.

As shown in FIG. 7B, the light-emitting device 6 further includes an adhesive layer A located between the upper surface 10a of the substrate 10 and the semiconductor stack 12, and is used to connect the substrate 10 and the semiconductor stack 12.

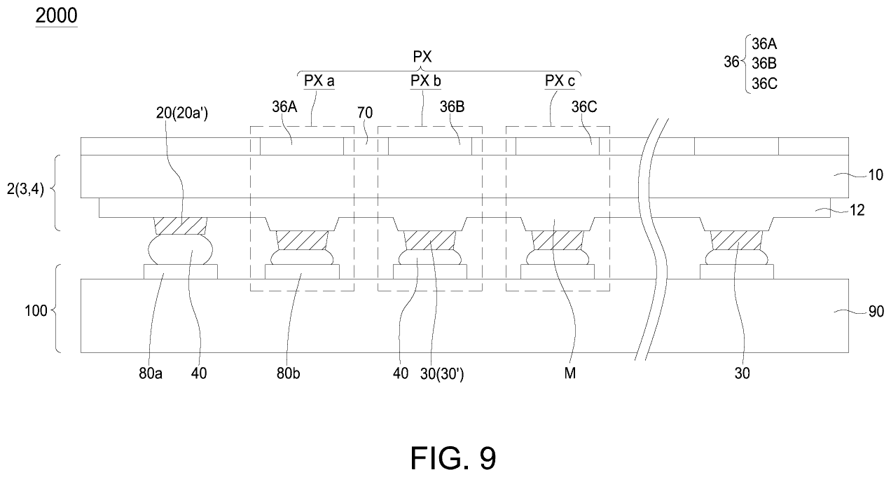

FIG. 9 shows a schematic cross-sectional view of a display device 2000 in accordance with an embodiment of the present application. The display device 2000 includes the driving backplane 100 and any one of the light-emitting devices 2, 3, 4, 5 or 6 connected thereto. In order to make the figure clear and concise, the light-emitting devices 2, 3, 4, 5 or 6 is schematically shown in FIG. 9. The detailed structures of the light-emitting devices 2, 3, 4, 5 or 6 should be referred to descriptions of the aforementioned embodiments. Since the first electrode pads 20 of the light-emitting devices 2, 3, 5 and 6 and the protrusion 20a′ of the first electrode pad 20 of the light-emitting device 4 are disposed in the non-operational region R2 and are not located between the adjacent second electrode pads 30 or 30′, the gap between the adjacent mesas M can be smaller, so that the number of mesas M per unit area can be increased, thereby improving the resolution of the display device 2000. In addition, process tolerance during bonding the light-emitting devices 2, 3, 4, 5 or 6 to the driving backplane 100 can be improved.

In accordance with the embodiments of the present application, current can be conducted through the plurality of first contact parts 201 of the contact metal and the first current spreader 202 of the light-emitting devices 1 to 3, 5 (or the first electrode pad 20′ of the light-emitting device 4) located around each mesa M and between the adjacent mesas M, which can increase the current uniformity and brightness uniformity among the mesas M in the light-emitting device. In addition, in general, the smaller the gap between the adjacent mesas M in the light-emitting device is, the higher the resolution of the display device has. However, the smaller the gap between the adjacent mesas M, the smaller the area of the upper surface 121a of the first semiconductor layer 121 is, and the size of the electrode that can be formed on the upper surface 121a is limited. In some embodiments of the present application, the plurality of first contact parts 201 is arranged between and around the adjacent mesas M, and an entire electrode layer (such as the first current spreaders 202 of the light-emitting devices 1 to 3 or the first electrode pad 20′ of the light-emitting device 4) contacts the first contact parts 201 through the openings of the insulating structure. The first current spreaders 202 of the light-emitting devices 1 to 3 and the first electrode pad 20′ of the light-emitting device 4 are electrically insulated with the mesas M by the insulating structure, so the widths of the first current spreader 202 and the first electrode pad 20′ are not limited by the gap between adjacent mesas M.

In some other embodiments, the light-emitting device in accordance with any embodiment of the present application can be devoid of the substrate 10. For example, during the manufacturing process of the light-emitting devices 1 to 6, the substrate 10 is separated from the semiconductor stack 12. As a result, the display device having the light-emitting device does not have a substrate 10 as well. The wavelength modulation layer 36 and/or the opaque layer 70 are located on the light extraction surface of the light-emitting device. That is, the surface of the semiconductor stack 12 opposite to the driving backplane 100. In addition, in another embodiment for forming the mesas M, the substrate 10 is separated from the semiconductor stack 12 so that a surface of the first semiconductor 121 is exposed after separating the substrate 10. Portions of the first semiconductor 121, the active region 123 and the second semiconductor layer 122 can be removed downward from the exposed surface of the first semiconductor 121 until a surface of the second semiconductor layer 122 is exposed, and each mesa M is surrounded by the exposed surface of the second semiconductor layer 122. Then, the contact metal, the first insulating structure, the current spreading electrode, the second insulating structure and the electrode pad structure are formed in accordance with the aforementioned process.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A light-emitting device, comprising:
a semiconductor stack, comprising a first semiconductor layer and a plurality of mesas spaced apart from each other on the first semiconductor layer, wherein the plurality of mesas each comprises a second semiconductor layer, the first semiconductor layer and the second semiconductor layer have different conductivity types;
a contact metal formed on the semiconductor stack, comprising a plurality of first contact parts located between the mesas and electrically connected to the first semiconductor layer, and a plurality of second contact parts located on the mesas and electrically connected to the second semiconductor layer;
a first insulating structure formed on the contact metal, comprising a plurality of first openings corresponding to the first contact parts and a plurality of second openings corresponding to the second contact parts;
a current spreading electrode formed on the first insulating structure, comprising a first current spreader and a plurality of second current spreaders, wherein the first current spreader is located between the mesas and filled in the first openings to connect the first contact parts and the second current spreaders are formed on the mesas and filled in the second openings to connect the second contact parts;
a second insulating structure formed on the current spreading electrode, comprising a third opening on the first current spreader and a plurality of fourth openings formed on the second current spreaders; and
an electrode pad structure formed on the second insulating structure, comprising at least one first electrode pad filled in the third opening to connect to the first current spreader, and a plurality of second electrode pads filled in the fourth openings to connect the second current spreaders.

2. The light-emitting device according to claim 1, wherein parts of the second contact parts form a second contact group and the second contact group is located on one of the mesas; and
wherein in a plan view, one of the fourth openings is located between the second contact parts within the second contact group.

3. The light-emitting device according to claim 2, wherein one of the second current spreaders overlaps each of the second contact parts in the second contact group.

4. The light-emitting device according to claim 2, wherein in a plan view, the second contact parts in the second contact group are arranged symmetrically with respect to a center of the second semiconductor layer of the one of the mesas.

5. The light-emitting device according to claim 1, wherein the plurality of mesas comprises a first mesa and a second mesa adjacent to each other, and parts of the plurality of the first contact parts form a first contact group located between the first mesa and the second mesa, and
wherein in a plan view, the third opening is located between the first contact parts within the first contact group.

6. The light-emitting device according to claim 1, wherein one of the first insulating structure and the second insulating structure comprises a plurality of first sub-layers and a plurality of second sub-layers with different refractive indexes alternately stacked.

7. The light-emitting device according to claim 1, wherein the at least one first electrode pad comprises multiple first electrode pads, and the multiple first electrode pads are respectively located between the plurality of mesas.

8. The light-emitting device according to claim 1, wherein each of the plurality of mesas comprises side walls and a top surface, and the first current spreader covers the side walls and the top surface of each of the plurality of mesas.

9. The light-emitting device according to claim 8, wherein the first current spreader and the second current spreaders do not overlap each other and a minimum distance is set therebetween, and the minimum distance is greater than or equal to a minimum distance between two adjacent mesas of the plurality of mesas.

10. The light-emitting device according to claim 1, wherein the first current spreader comprises a protrusion located outside the plurality of mesas,
wherein the third opening is located on the protrusion, and the first electrode pad is filled in the third opening and connected to the protrusion.

11. The light-emitting device according to claim 10, wherein in a plan view, the first semiconductor layer comprises an edge and the first electrode pad is disposed along the edge.

12. The light-emitting device according to claim 1, further comprising a transparent conductive layer formed between the second semiconductor layer and the second contact parts.

13. The light-emitting device according to claim 1, wherein a minimum distance between the second contact parts and an edge of the second semiconductor layer is greater than 5 μm.

14. The light-emitting device according to claim 1, wherein a minimum distance between the second contact parts and an edge of the second semiconductor layer is greater than a minimum distance between one of the first contact part and one of the mesas.

15. The light-emitting device according to claim 1, wherein in a plan view, one of the second current spreaders has an area larger than that of one the second contact parts and smaller than that of the second semiconductor layer of one of the mesas.

16. The light-emitting device according to claim 1, wherein a minimum distance between two adjacent mesas of the plurality of the mesas ranges from 5 μm to 50 μm.

17. The light-emitting device according to claim 1, wherein in a plan view, one of the plurality of the mesas has a maximum width ranging from 20 μm to 500 μm.

18. The light-emitting device according to claim 1, wherein the first contact parts are located at an edge of the light-emitting device.

19. A light-emitting device, comprising:
a semiconductor stack, comprising a first semiconductor layer and a plurality of mesas spaced apart from each other on the first semiconductor layer, wherein the plurality of mesas each comprises a second semiconductor layer, the first semiconductor layer and the second semiconductor layer have different conductivity types;
a contact metal formed on the semiconductor stack, comprising a plurality of first contact parts located between the mesas and electrically connected to the first semiconductor layer, and a plurality of second contact parts located on the mesas and electrically connected to the second semiconductor layer;
a first insulating structure formed on the contact metal, comprising a plurality of first openings corresponding to the first contact parts and a plurality of second openings corresponding to the second contact parts; and
an electrode pad structure formed on the first insulating structure, comprising a first electrode pad filled in the first openings to connect to the first contact parts, and a plurality of second electrode pads filled in the second openings to connect the second contact parts;
wherein the first electrode pad comprises a protrusion located outside the plurality of mesas and extending toward an edge of the light-emitting device.

20. A display device, comprising:
a light-emitting device comprising:
a semiconductor stack, comprising a first semiconductor layer and a plurality of mesas spaced apart from each other on the first semiconductor layer, wherein the plurality of mesas each comprises a second semiconductor layer, the first semiconductor layer and the second semiconductor layer have different conductivity types;
a contact metal formed on the semiconductor stack, comprising a plurality of first contact parts located between the mesas and electrically connected to the first semiconductor layer, and a plurality of second contact parts located on the mesas and electrically connected to the second semiconductor layer;
a first insulating structure formed on the contact metal, comprising a plurality of first openings corresponding to the first contact parts and a plurality of second openings corresponding to the second contact parts;
a current spreading electrode formed on the first insulating structure, comprising a first current spreader and a plurality of second current spreaders, wherein the first current spreader is located between the mesas and filled in the first openings to connect the first contact parts and the second current spreaders are formed on the mesas and filled in the second openings to connect the second contact parts;
a second insulating structure formed on the current spreading electrode, comprising a third opening on the first current spreader and a plurality of fourth openings formed on the second current spreaders; and
an electrode pad structure formed on the second insulating structure, comprising at least one first electrode pad filled in the third opening to connect to the first current spreader, and a plurality of second electrode pads filled in the fourth openings to connect the second current spreaders; and
a driving backplane, comprising a carrier and a driving circuit formed on the carrier;
wherein the light-emitting device is bonded to the driving backplane and electrically connected to the driving circuit.
